(19) United States
(12) Patent Application Publication
(10) Pub. No.: US 2002/0000370 A1
(43) Pub. Date: Jan. 3, 2002

(54) ION PROCESSING OF A SUBSTRATE

(76) Inventors: RICHARD J. POMMER, TRABUCO CANYON, CA (US); GLEN ROETERS, HUNINGTON BEACH, CA (US); STEPHEN M. AVERY, COSTA MESA, CA (US)

Correspondence Address: LESLIE WEISE, ALLIEDSIGNAL INC, 101 COLUMBIA ROAD, P O BOX 2245, MORRISTOWN, NJ, 079621057

(21) Appl. No.: 09/369,032

(22) Filed: Aug. 4, 1999

(51) Int. Cl. B44C 1/22; C23C 14/32

(52) U.S. Cl. 204/192.14; 204/192.15; 204/192.34; 204/192.35; 204/192.36; 216/17; 216/65; 216/66; 216/94; 134/1.1

(57) ABSTRACT

The use of ion beam processing in preparation of a substrate's surfaces, particularly a polyimide film such as Upilex®-SS, prior to depositing a metal on the substrate surfaces. In one aspect, the ion beam processing can be used to remove relatively unique forms of surface contaminants without requiring additional cleaning by traditional methods such as chemical or plasma cleaning. In another aspect, the ion beam processing utilizing an anode layer ion source can be used to prepare polyimide films prior to metal deposition to produce substrates having surprisingly good peel strengths. In still another aspect, ion beam processing can be used to minimize differences in surface characteristics between opposite sides of a substrate.

### FIELD OF THE INVENTION

The field of the invention is substrate surface preparation.

### BACKGROUND OF THE INVENTION

An integrated circuit (IC) package is a housing which environmentally protects the IC, facilitates testing of the IC, and facilitates the use of the IC in high-yield assembly processes. Such a package functions to protect an IC from mechanical and environmental stresses and electrostatic discharge. It also functions to provide a mechanical interface for testing, burn-in, and interconnection to a higher level of packaging such as a circuit card.

In many IC packages a substrate acts as an interconnecting layer between the terminals or pads on the IC, and the connectors or leads of the package. The substrate is typically mechanically and electrically coupled to both the IC and the package leads. The substrate may be made from a ceramic or organic material, may be rigid or flexible, and may comprise a single layer or multiple layers laminated together.

A substrate typically has two substantially planar sides located on opposite sides of the substrate. A substrate may include conductive patterns located on one or both of the planar sides, and may include conductive through holes or vias to provide a conductive path through the substrate. Substrate fabrication may include the steps of providing a base layer such as a polyimide film, forming vias in the base layer, covering the planar surfaces of the base layer with one or more metal layers and filling the vias with conductive material, removing portions of the metal layers to form the conductive pattern, and possibly coupling the resulting substrate with additional substrates to form a multi-layer substrate.

The step of forming vias in the base layer may be accomplished through the use of laser drilling. Although laser drilling provides many benefits, it typically leaves surface contaminants (“laser slag”) on the substrate surfaces. These surface contaminants are preferably removed prior to covering the surfaces with the metal layers. Although chemical and plasma cleaning methods are known, improvements in substrate cleaning have the potential of providing substantial economical and environmental savings.

The step of covering the surfaces of the base layer with one or more metal layers and filling the vias with conductive material is preferred to result in sufficient adhesion of the metal layers to the base layer so as to prevent future delamination. A measure of the ability to resist delamination is peel strength. Peel strength is typically measured as units of force per unit width such as lb/in or g/mm and is determined by measuring the amount of force required to peel a strip of the metal layer from the base layer. In addition to having a sufficiently high peel strength, the metal layers must be sufficiently thick so as to survive future processing such as chemical etching.

One method for preparing the surface of a substrate for metal deposition via sputtering is to use an ion source to etch the surfaces prior to sputtering. U.S. Pat. No. 5,068,020, for example, discusses subjecting a surface of a substrate to contact with a stream of ions of an inert gas to change the surface characteristics of the substrate. It is also known to utilize Kaufman and DC Glow ion sources to bombard polyimide film substrates such as Upilex® with O₂⁺ ions. However, existing methods and devices sometimes produce an unsatisfactory result in that the resulting coated substrate suffer from relatively poor peel strength on one or more sides. Thus, it is desirable to develop new substrates having higher peel strengths, and methods and devices for producing such substrates.

### SUMMARY OF THE INVENTION

The present invention is directed to the use of ion beam processing in preparation of a substrate's surfaces, particularly a polyimide film such as Upilex®, prior to depositing a metal on the substrate surfaces. In one aspect, the ion beam processing can be used to remove relatively unique forms of surface contaminants without requiring additional cleaning by traditional methods such as chemical or plasma cleaning. In another aspect, the ion beam processing utilizing an anode layer ion source can be used to prepare polyimide films prior to metal deposition to produce substrates having surprisingly good peel strengths. In still another aspect, ion beam processing can be used to minimize differences in surface characteristics between opposite sides of a substrate.

Various objects, features, aspects and advantages of the present invention will become more apparent from the following detailed description of preferred embodiments of the invention, along with the accompanying drawings in which like numerals represent like components.

### BRIEF DESCRIPTION OF THE DRAWINGS

FIG. 1 is a block diagram of a first method embodying the invention.

FIG. 2 is a block diagram of a second method embodying the invention.

FIG. 3 is a block diagram of a third method embodying the invention.

FIG. 4 is a block diagram of a fourth method embodying the invention.

FIG. 5 is a block diagram of a fifth method embodying the invention.

FIG. 6 is a schematic view of a preferred ion source.

FIG. 7 is a schematic view of a sputtering chamber modified for use with the preferred methods.

### DETAILED DESCRIPTION

A preferred method of preparing a substrate for future processing involves providing a base material such as a polyimide or other dielectric film, laser drilling vias into the base material, subjecting the base material to ion-beam processing, and sputtering metal layers such as chromium and copper onto the dielectric film.

The step of laser drilling vias into the base material (“lasing”) was found to leave a carbonaceous ring (“laser slag”) around the entry hole of the via. Such rings are particularly troublesome in that there is little or no adhesion between the laser slag and the sputtered metal layers. Although chemical and plasma cleaning methods for removing laser slag are known, their use proved undesirable as being expensive in regard to time and materials used as well as having a detrimental environmental impact.

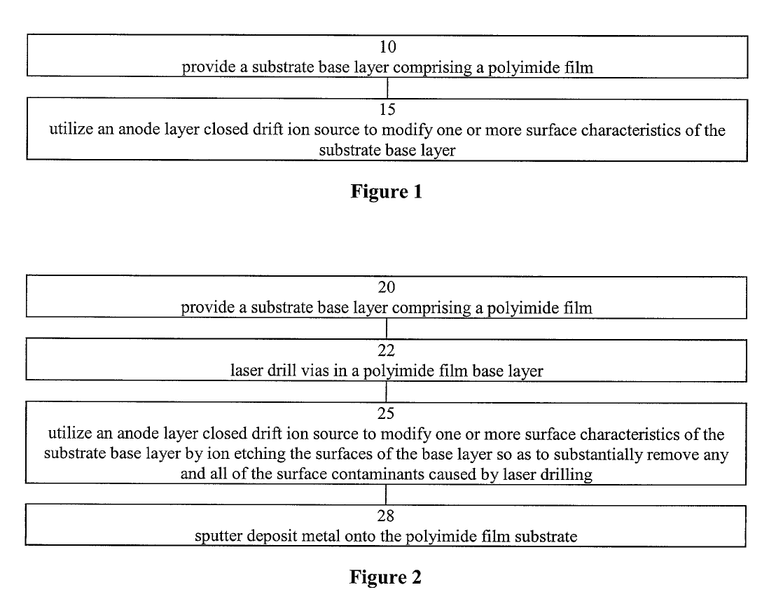

One possible solution to the “laser slag” problem is illustrated in FIG. 1, in which, in step 10, a substrate is provided, and, in step 15, is processed via an anode layer closed drift ion source to modify one or more surface characteristics of the substrate. Referring to FIG. 2, the solution of FIG. 1 (step 20 of FIG. 2 corresponds to step 10 of FIG. 1, and step 25 of FIG. 2 corresponds to step 15 of FIG. 1) is used as part of a process which includes a laser drilling step 22, and in which the surface modification step 25 removes substantially all of the surface contaminants formed by the laser drilling of step 22, and in which the surface modification of step 25 is followed by a sputter deposition step 28. During the deposition step 28, opposite sides of the substrate are coated with metal, preferably chromium and copper.

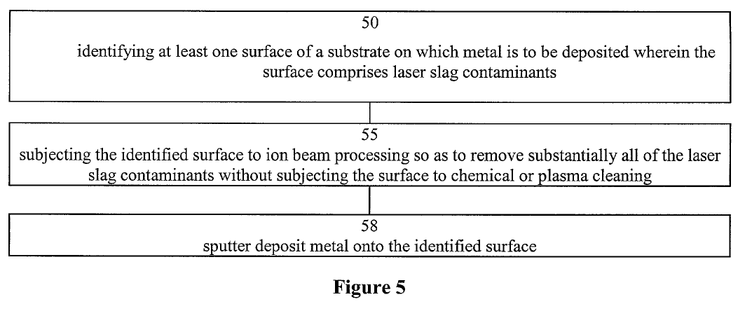

Including step 25, preparing the surface by ion etching, permits the use of one or more ion sources to remove the laser slag as well as other surface contaminants. The use of ion etching for these purposes potentially eliminates the need for chemical and/or plasma cleaning steps between lasing and sputtering steps, and promotes adhesion during step 28, sputtering metal onto the cleaned and prepared film. FIG. 5 provides an alternative illustration of the method in which emphasis on eliminating any chemical and/or plasma cleaning step is emphasized, and where steps 50, 55, and 58 correspond to steps 20, 25 and 28 of FIG. 2, respectively.

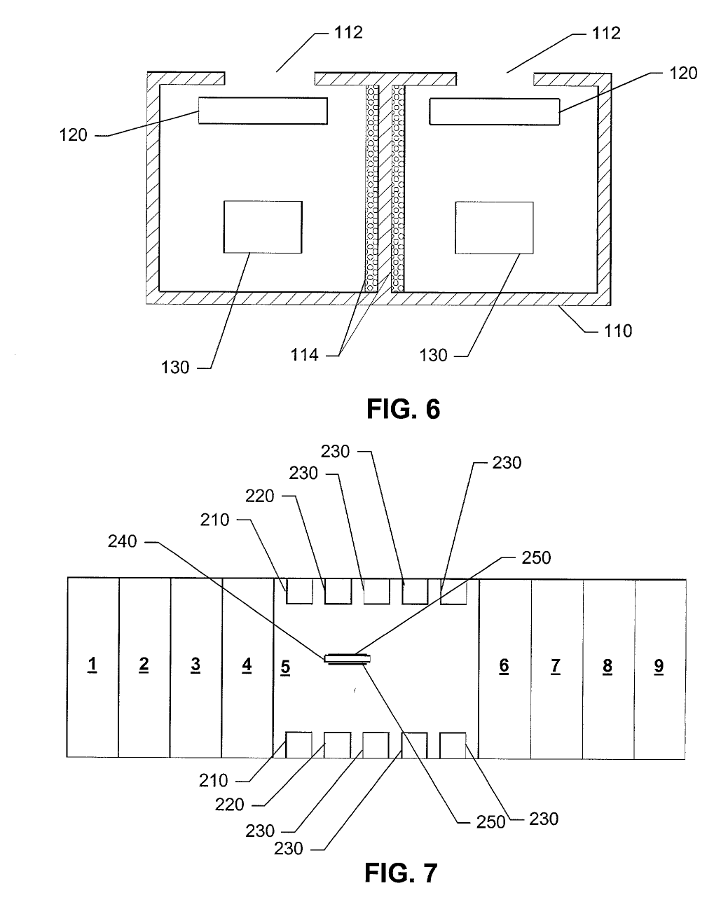

For the ion source(s) of step 25, it is preferred that a closed drift device (a device having an electron current that passes through and is impeded by a magnetic field) be used. Even more preferably, a direct current, anode layer/gridless devices having a short acceleration zone would be used. Referring to FIG. 6, such a device typically comprises a ferromagnetic cathode 110, an anode 120, ion beam slits 112, magnetic windings 114, and a gas feed manifolds 130. Such a device can work without an electron emitter, has a simpler design and exhibits less electrical noise than a source with an extended acceleration zone, minimizes or eliminates particle contamination and is relatively maintenance-free. In a preferred embodiment, an Advanced Energy Industries, Inc. 94 cm Linear Ion Beam Source was used with Oxygen as a working gas, a gas flow pressure of 200 sccm (standard cubic centimeters per minute), a discharge voltage (which is function of gas flow) of 1500v for a 200 sccm gas flow. The use of an anode layer closed drift device as an ion source has led to surprisingly good peel strengths. Peel strengths of up to 8 lb/in (see Table 1) have been measured for substrates subjected to ion processing with the preferred source.

It is thought that the use of multiple ion sources will allow fewer oscillations and/or a faster shuttle speed so as to increase throughput. It is also contemplated that multiple ion sources could be used with one or more sources configured to provide optimum cleaning and one or more other sources configured to provide optimum surface preparation. As an alternative to having two sources, a substrate could be etched in at least one cleaning pass and at least one preparation pass in front of a single source with the configuration of the ion source being varied between cleaning and preparation passes. For multi-source devices, a configuration for optimum cleaning may include establishing differing orientations between the sources so as to result in different impact angles of the ion beams in relation to the substrate.

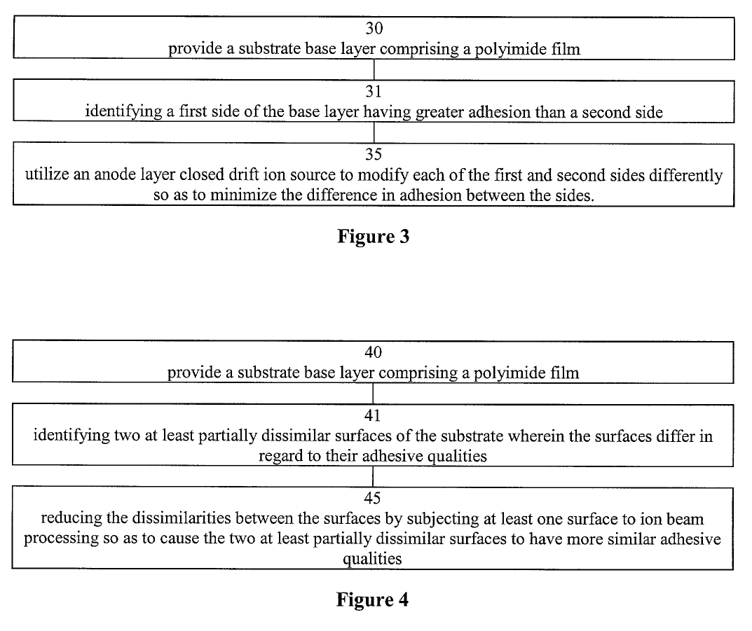

Opposite surfaces of polyimide films such as Upilex® tend to have differing adhesion qualities with a resultant difference in peel strengths. It is contemplated that multi-source or multi-pass etching might be used to prepare the surface so as to promote more balanced peel strengths between the sides. Contemplated processes are illustrated in FIGS. 3 and 4. As part of the process, each side would be identified as to whether it was or was not the side having a higher adhesive value (steps 31 and 41). Each side would subsequently be subjected to processing at lest partially customized to match the adhesiveness of the side (steps 35 and 45) with the goal to be achieving higher and more balanced peel strengths.

It is currently preferred that the ion etch process be accomplished in situ with the sputtering process. One method of achieving this is to modify an existing sputtering system to include the preferred ion source. This has been accomplished by building a modified version of a Balzers Process Systems (BPS) Aristo™ 500S vertical in-line sputtering system for Flat Panel Displays. Referring to FIG. 7, although previously used only to sputter a single side of a flat panel display, such a system can be modified to handle polyimide panels 250 and to utilize high energy plasma sources 210 (such as the Advanced Energies ion source) by replacing a pair of cathodes with the ion sources 210. The current system comprises a substrate carrier 240, ion sources 210, as previously discussed, to provide a high energy directed plasma source to clean and texture the outward facing surface of film panels 250 immediately before metalization, and a series of modules arranged linearly (and numbered in ascending order from start to finish) wherein the end modules (modules 1 and 9) allow for atmospheric for loading and unloading, modules 2 and 8 cycle between atmospheric pressure and rough vacuum levels and act as load locks, modules 3 and 7 cycle between rough vacuum levels of the load locks, and the high vacuum levels of the process chambers, and modules 4-6 are continuous (modules 1-3 and 7-9 are each discontinuous/physically separated to allow for differing vacuum levels) and include the ion sources 210 and cathodes 220 and 230 which are in module 5, and additional space in modules 4 and 6 for the carrier to move past the ion sources 210 and cathodes 220 and 230 for complete preparation and sputter coverage of the substrate panels. In module 5 there is at least one pair of ion sources 210, at least one pair of chromium cathodes 220, and at least one pair of copper cathodes 230, with the sources and cathodes being paired with paired sources mounted on opposing walls facing inward.

Using the modified Balzer system with the Advanced Energy source, peel strengths were typically between 4 lb/in and 8 lb/in for Upilex®-SS film as shown by the test results of Table 1. The results of Table 1 were obtained by ion-etching Upilex(&-SS film with the substrate carrier carrying the substrate past the ion source moving at a speed of 4 meters per minute and passing by the ion source 20 times (10 times in each direction), using an O₂ and Ar mixture which was 75% O₂, and with the other parameters as specified in the table.

| | | | | Peel Strength | Peel Strength |
|---|---|---|---|---|---|
| | | Peel | Peel | After Pressure | After Pressure |
| Sam- | Flow of | Strength, | Strength, | Cooker | Cooker |
| ple | O₂ | Side 1 | Side 2 | Processing, | Processing, |
| # | (sccm) | (lb/in) | (lb/in) | Side 1 (lb/in) | Side 2 (lb/in) |
| 1 | 65 | 5.4 | 6.4 | 3.6 | 5.44 |
| 2 | 48 | 5.12 | 7.2 | 3.36 | 5.72 |
| 3 | 48 | 3.92 | 6.32 | 3.4 | 5.48 |
| 4 | 140 | 4.8 | 8 | 3.76 | 6 |
| Avg.: | | 4.81 | 6.98 | 3.53 | 5.66 |

It has been found that over-processing a polyimide substrate results in decreased peel strengths. Thus, it is contemplated that preferred methods will limit processing so as to prevent such decreases in peel strengths with the limits preferably being applied to the flow rate of O₂ and the length of time any given portion of the substrate is subjected to ion beam processing. Time might be controlled by adjusting the speed of the substrate carrier or the number of oscillations of the substrate within the etching/sputtering chamber. It is contemplated that the decrease in adhesion results from a breakdown of the polymer chains of the polyimide film. Thus, processing should be controlled so as to prevent such a breakdown or otherwise to maximum the resultant peel strength of any layer sputtered onto the substrate. To stay within the limit, for an ion source gas flow rate of 200 sccm, an ion source input power of 600 W, and a substrate carrier/shuttle speed of 2 m/min the preferred number of oscillations is 10.

Thus, specific embodiments and applications of ion etching systems and methods for their use in cleaning and preparing substrate prior to metal deposition have been disclosed. It should be apparent, however, to those skilled in the art that many more modifications besides those already described are possible without departing from the inventive concepts herein. For example, alternative anode layer ion sources can be used. Similarly, different sputtering systems might be utilized as may different lasing systems. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

What is claimed is:

1. A method for substrate preparation comprising:
providing a substrate comprising a dielectric film;
utilizing an anode layer closed drift ion source to modify one or more surface characteristics of the substrate.

2. The method of claim 1 further comprising laser drilling vias into the substrate prior to surface modification utilizing the ion source and wherein the use of the ion source to modify one or more surface characteristics of the substrate results in the removal of substantially all the surface contaminants caused by the laser drilling.

3. The method of claim 2 further comprising sputtering metal layers onto the substrate wherein no chemical or plasma cleaning of the substrate occurs after the laser drilling and before the sputtering are accomplished.

4. The method of claim 3 wherein the peel strength of at least one metal layer sputtered onto the substrate is greater than N lb/in wherein N is one of 5, 6, 7, and 8.

5. The method of claim 1 further comprising identifying a first side having greater adhesion than a second side, wherein the ion source is used to modify each surface differently so as to minimize the difference in adhesion between the sides.

6. The method of claim 1 further comprising the step of limiting utilization of the anode layer closed drift ion source to modify one or more surface characteristics of the substrate so as to maximize the peel strength of any layer sputtered onto the substrate.

7. The method of claim 1 wherein the dielectric film is a polyimide.

8. The method of claim 7 wherein the dielectric film is Upilex®-SS.

9. A method of preparing a substrate for metal deposition by balancing the surface characteristics of the substrate comprising the steps of:
identifying two at least partially dissimilar surfaces of the substrate;
reducing the dissimilarities between the surfaces by subjecting at least one surface to ion beam processing.

10. The method of claim 9 wherein the two at least partially dissimilar surfaces differ in regard to their adhesive qualities, and subjecting at least one surface to ion beam processing results in the surfaces having more similar adhesive qualities.

11. A method of preparing a substrate for metal deposition by removing laser slag from the substrate without utilizing chemical or plasma cleaning comprising the steps of:
identifying at least one surface of the substrate on which metal is to be deposited wherein the surface comprises laser slag contaminants;
subjecting the identified surface to ion beam processing so as to remove substantially all of the laser slag contaminants without subjecting the surface to chemical or plasma cleaning.

12. The method of claim 11 further comprising providing at least two ion sources wherein one source is configured to remove surface contaminants and the second source is configured to promote adhesion between the substrate and a sputtered coating.
